(19) United States
(12) Patent Application Publication
(10) Pub. No.: US 2002/0047728 A1
(43) Pub. Date: Apr. 25, 2002

(54) Integrated circuit

(76) Inventors: Joachim Held, Munchen (DE); Thomas Steinecke, Hofsingelding (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/839,767

(22) Filed: Apr. 20, 2001

(30) Foreign Application Priority Data
Apr. 20, 2000 (DE) 100 19 811.2

(51) Int. Cl. G01R 1/00; H03K 5/00; H03D 3/00

(52) U.S. Cl. 327/39; 327/1

(57) ABSTRACT

An integrated circuit is described which is distinguished by the fact that there is integrated in it an RF filter device which can prevent or restrict the propagation of high-frequency interference signals through lines carrying DC voltages or low-frequency voltages. As a result, interference with the operation of the integrated circuit and/or of other integrated circuits or of other components of the system containing the integrated circuit can be prevented in a very simple yet extremely effective manner.

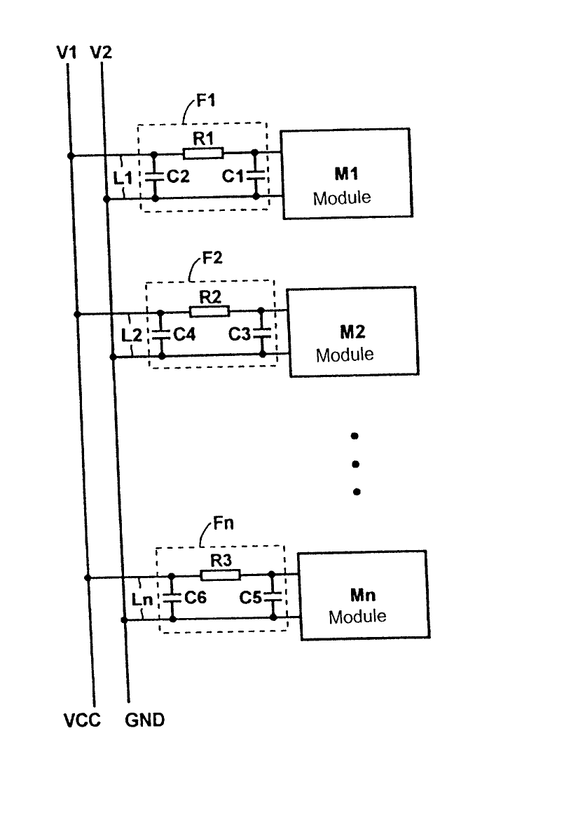

### BACKGROUND OF THE INVENTION

### FIELD OF THE INVENTION

The present invention relates to an integrated circuit.

Integrated circuits have been known for many years in innumerable embodiments and need no further explanation.

A known problem of integrated circuits is that they occasionally react sensitively to high-frequency interference signals and themselves generate (for example by generating signals with steep edges) high-frequency interference signals which can interfere with other components of the system containing the integrated circuit.

In order to avoid this, external filters provided outside the integrated circuit and/or particular layouts of the integrated circuit and/or of the configuration containing the integrated circuit have been used heretofore.

Experience shows that, despite these measures, it is not always and everywhere possible to eliminate the above-mentioned problem. Furthermore, the provision of external filters and/or the use of a particular layout are associated with a relatively high outlay.

### SUMMARY OF THE INVENTION

It is accordingly an object of the invention to provide an integrated circuit that overcomes the above-mentioned disadvantages of the prior art devices of this general type, in which a feasible way of making it possible, in a simple manner, to reliably avoid interfering with the operation of integrated circuits by high-frequency interference signals, and/or interference with integrated circuits or other system components by high-frequency interference signals generated by the integrated circuit.

With the foregoing and other objects in view there is provided, in accordance with the invention, an integrated circuit containing lines, including a first line and a second line, for carrying DC voltages or low-frequency voltages. A radio-frequency (RF) filter device is connected to the lines and prevents and restricts a propagation of high-frequency interference signals through the lines.

The integrated circuit according to the invention is distinguished by the fact that there is integrated in it the RF filter device which can prevent or restrict the propagation of high-frequency interference signals via lines carrying DC voltages or low-frequency voltages.

The integration of the RF filter device in the integrated circuit proves to be advantageous in many respects.

One of the advantages is that the RF filter device provided in the integrated circuit can effectively block RF interference signals that reach the integrated circuit and/or are generated in the latter. There are two reasons for this. First because the RF interference signals can be filtered out directly where their occurrence would be interfering, or where they are generated, and second because the elements from which the RF filter device is constructed, that is to say, in particular, one or more capacitors and, if appropriate, one or more resistors, can be optimally dimensioned and retain their properties essentially unchanged under all circumstances.

By virtue of the fact that the RF interference signals can be filtered out directly where their occurrence would be interfering, or where they are generated, the RF filter device can also filter out interference signals which arise only within the integrated circuit. These include, in particular, those interference signals which are generated by constituent parts of the integrated circuit that is to be protected, and/or interference signals which are carried into the integrated circuit by the action of electromagnetic radiation on lines running within the integrated circuit. External filters cannot afford protection against such interference signals.

The fact that RF filter devices integrated in the integrated circuit can be optimally dimensioned is because the properties of the components used therefor, i.e. the capacitances, resistors, etc., can be exactly adapted to the individual requirements without any difficulties. In contrast to this, the discrete components required for external filters have to be selected from among the commercially available components, which generally have only predetermined standard values, as a result of which it is at best a matter of chance if the external filters have exactly the desired properties.

The fact that the RF filter devices integrated in the integrated circuit retain their properties essentially unchanged under all circumstances is because, in particular, capacitors integrated in integrated circuits have essentially exclusive capacitive properties. In contrast to this, capacitors formed as discrete elements also have inductive properties in addition. The equivalent circuit diagram of such a capacitor contains a series circuit formed by a capacitor and a coil, resulting in that a capacitor in the form of a discrete component is, strictly speaking, a LC series resonant circuit. As is known, LC series resonant circuits have capacitive properties for frequencies lying below the resonant frequency, and inductive properties for frequencies lying above the resonant frequency. Therefore, an external filter constructed using a capacitor in the form of a discrete component can fulfill its task only for frequencies lying below the resonant frequency. Capacitors integrated in integrated circuits are formed by electrically conductive structures on layers of the integrated circuit that lie one above the other, and the capacitors therefore have no or negligible inductive properties. As a result, such capacitors can fulfill the task incumbent upon them right into the highest frequency ranges.

The provision of the RF filter device integrated in the integrated circuit at least partially obviates the need to provide external filters and/or to use particular layouts.

The RF filter devices can be integrated in integrated circuits simply and without any difficulties, with the result that the above-mentioned advantages can be obtained without accepting appreciable disadvantages.

The integration of the RF filter device in an integrated circuit is thus a very simple possibility, but one that is nevertheless extremely effective under all circumstances, for preventing interference with the operation of integrated circuits by high-frequency interference signals, and/or interference with other integrated circuits or other system components by high-frequency interference signals generated by integrated circuits.

In accordance with an added feature of the invention, component parts are connected to the RF filter device. The RF filter device is disposed, constructed and dimensioned such that the component parts are protected against the high-frequency interference signals transmitted through the lines and fed to the component parts.

In accordance with an additional feature of the invention, the component parts generate and output further high-frequency interference signals carried by the lines. The RF filter device is disposed, constructed and dimensioned such that the RF filter device filters out the further high-frequency interference signals generated and output by the component parts and carried on the lines.

In accordance with another feature of the invention, component parts are connected to the lines and generate and output further high-frequency interference signals carried by the lines. The RF filter device is disposed, constructed and dimensioned such that the component parts are protected against the high-frequency interference signals and also protected against the further high-frequency interference signals generated within the integrated circuit.

In accordance with a further feature of the invention, there are component parts to be protected against the high-frequency interference signals. The RF filter device is disposed in direct proximity and connected to the component parts for suppressing the high-frequency interference signals. The component parts generate further high-frequency interference signals that are also suppressed by the RF filter device to prevent interferences in others of the component parts and to parts external to the integrated circuit.

In accordance with an another added feature of the invention, there are component parts connected to the RF filter device. The RF filter device is disposed, constructed and dimensioned such that the RF filter device filters out the high-frequency interference signals transmitted through the lines supplying energy required for operation. The component parts generate further high-frequency interference signals and the RF filter device suppresses the further high-frequency interference signals to prevent interference in others of the component parts and to parts external to the integrated circuit.

In accordance with another additional feature of the invention, the RF filter device has a capacitor, through which the first line from which the RF filter device is intended to remove the high-frequency interference signals is connected to a reference-ground potential.

In accordance with another further feature of the invention, the RF filter device has a resistor inserted into the first line from which the RF filter device is intended to remove the high-frequency interference signals.

In accordance with an added feature of the invention, the RF filter device has a further second capacitor, through which the first line from which the RF filter device is intended to remove the high-frequency interference signals is connected to the reference-ground potential.

In accordance with an additional feature of the invention, there are component parts generating further high-frequency interference signals and are connected to the lines. The resistor and the capacitor form a low-pass filter at least partially preventing the high-frequency interference signals from reaching the component parts that are to be protected against the high-frequency interference signals. In addition, the RF filter device suppresses the further high-frequency interference signals from each of the component parts from reaching other ones of the component parts and from reaching outside of the integrated circuit.

In accordance with another feature of the invention, there are provided component parts each generating further high-frequency interference signals and are connected to the lines. The resistor and the further capacitor form a low-pass filter at least partially preventing the high-frequency interference signals from reaching the component parts which are to be protected against the high-frequency interference signals by the RF filter device. The RF filter device also suppresses the further high-frequency interference signals from each of the component parts from reaching other ones of the component parts and from reaching outside of the integrated circuit.

In accordance with a further feature of the invention, the capacitor is dimensioned such that energy fed through the lines, connected to the RF filter device, can be drawn completely from the capacitor given regular or continuous recharging of the capacitor. There are provided component parts each generating further high-frequency interference signals and are connected to the lines. The RF filter device protects the component parts against the high-frequency interference signals, and the RF filter device suppresses the further high-frequency interference signals of each of the component parts from reaching other ones of the component parts and from reaching outside of the integrated circuit.

In accordance with yet another feature of the invention, the resistor is dimensioned such that a current flowing through the resistor during operation suffices to keep the capacitor continually charged to such an extent that the energy fed through the lines provided with the RF filter device to the component parts can be drawn completely from the capacitor.

In accordance with yet another additional feature of the invention, the resistor is dimensioned such that the low-pass filter prevents a flowing of the high-frequency interference signals.

In accordance with yet another further feature of the invention, the resistor is dimensioned such that resonances which the capacitor and the further capacitor form with a rest of a system and among one another are reduced to a degree which does not interfere with an operation of the integrated circuit.

In accordance with a feature of the invention, the resistor is dimensioned such that the resistor converts the high-frequency interference signals filtered out by the RF filter device at least partially into heat.

In accordance with a concomitant feature of the invention, there is provided a plurality of component parts, and the RF filter device is one of a plurality of RF filter devices each connected to different ones of the component parts.

Other features which are considered as characteristic for the invention are set forth in the appended claims.

Although the invention is illustrated and described herein as embodied in an integrated circuit it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

The single figure of the drawing is a block diagram of an integrated circuit according to the invention.

### DESCRIPTION OF THE PREFERRED EMBODIMENTS

Referring now to the single figure of the drawing in detail, there is shown an integrated circuit with an exemplary embodiment of an RF filter device F1, F2 . . . Fn described in more detail below.

The integrated circuit described in more detail below is an arbitrary integrated circuit, that is to say, by way of example, a microprocessor, a microcontroller, a memory module, or an arbitrary other integrated circuit.

For the sake of completeness, at this early point attention shall be drawn to the fact that the constituent parts of the integrated circuit considered in the present case which are shown and described are only those which are of particular interest here. The construction, the function and the method of operation of the constituent parts of the integrated circuit that are not shown are known and need no further explanation.

The integrated circuit considered is distinguished by the fact that there is integrated in it the RF filter device F1, F2 . . . Fn which can prevent or restrict the propagation of high-frequency interference signals via lines carrying DC voltages or low-frequency voltages.

The integrated circuit considered contains a multiplicity of modules M1, M2, . . . Mn, which are connected via separate line pairs L1, L2, . . . Ln to supply lines V1 and V2 serving for the power supply of the modules M1, M2, . . . Mn. The supply line V1 carrying a positive potential designated here by VCC, and the supply line V2 carrying a neutral potential (ground potential) designated by GND.

In the example considered, the modules M1, M2, . . . Mn each contain specific functional units of the integrated circuit, i.e. the module M1 contains, for example, a memory block, the module M2 contains, for example, one or more I/O drivers, and the module Mn contains, for example, an A/D converter, etc.

A dedicated RF filter device F1, F2, . . . Fn is provided for each of the modules M1, M2, . . . Mn. In the example considered, the RF filter devices F1, F2, . . . Fn are disposed in such a way that they can prevent or restrict the propagation of high-frequency interference signals in the lines L1, L2, . . . Ln and the supply lines V1 and V2.

With regard to the supply lines V1, V2, it shall be noted at this early point that these lines can be configured as lines or as extensive structures in the same or in different planes of the integrated circuit.

The RF filter device F1 assigned to the first module M1 contains a first capacitor C1, a second capacitor C2, and a resistor R1. The RF filter device F2 assigned to the second module M2 contains a first capacitor C3, a second capacitor C4, and a resistor R2. The RF filter device F3 assigned to the third module M3 contains a first capacitor C5, a second capacitor C6, and a resistor R3.

The resistors of the respective RF filter devices are respectively inserted into one of the lines of the line pairs L1, L2, . . . Ln. In the example considered, the line is that line via which the module to which the respective RF filter device F1, F2, . . . Fn is assigned is connected to the supply line Vl carrying the potential VCC.

The capacitors of the respective RF filter devices F1, F2, . . . Fn are in each case disposed between the individual lines of the line pairs L1, L2, . . . L3 via which the module to which the respective RF filter device F1, F2, . . . Fn is assigned is connected to the supply lines V1 and V2. In this case, the respective first capacitors of the RF filter devices F1, F2, . . . Fn, i.e. the capacitors C1, C3 and C5, are situated between the resistor of the respective RF filter device F1, F2, . . . Fn and the module to which the relevant RF filter device F1, F2, . . . Fn is assigned, and the respective second capacitors of the RF filter devices, i.e. the capacitors C2, C4 and C6, are situated between the resistor of the respective RF filter device F1, F2, . . . Fn and the supply lines V1 and V2.

The RF filter devices F1, F2, . . . Fn are preferably disposed very near (as near as possible) to the modules M1, M2, . . . Mn to which the respective RF filter device F1, F2, . . . Fn is assigned.

The respective first capacitors of the RF filter devices F1, F2, . . . Fn, i.e. the capacitors C1, C3 and C5, and the resistors R1, R2, and R3 in each case form a low-pass filter which at least partially prevents high-frequency interference signals from passing into the modules M1, M2, . . . Mn via the line pairs L1, L2 and Ln.

The respective second capacitors of the RF filter devices F1, F2, . . . Fn, i.e. the capacitors C2, C4 and C6, and the resistors R1, R2, and R3 in each case form a low-pass filter which at least partially prevents high-frequency interference signals which are generated in the modules M1, M2, . . . Mn from passing via the line pairs L1, L2 and Ln onto the supply lines V1 and V2 and, via the latter, to other constituent parts of the integrated circuit or to points outside the integrated circuit (to other components of the system containing the integrated circuit).

The RF filter devices F1, F2, . . . Fn thus prevent or restrict both transmission of high-frequency interference toward the modules and transmission of high-frequency interference away from the modules.

The respective first capacitors of the RF filter devices, i.e. the capacitors C1, C3 and C5, are preferably dimensioned in such a way that the energy which has to be fed to the respective modules can, given regular or continuous recharging of the capacitors, be drawn completely from the first capacitors via those sections of the line pairs L1, L2, . . . Ln which run between the first capacitors C1, C3, and C5, respectively, and the supply lines V1 and V2, and the resistors R1, R2, . . . Rn.

The resistors R1, R2, and R3 are preferably dimensioned in such a way that currents which flow through them are large enough to supply the modules with the energy they require (to charge the first capacitors C1, C3 and C5 in such a way that the energy required by the modules can be drawn from them), and that the flowing of high-frequency currents between the modules and the supply lines is entirely prevented or at least greatly restricted by the low-pass filters formed by the resistors and the first capacitors and also by the resistors and the second capacitors.

The resistors prove not only to be advantageous because they form low-pass filters together with the capacitors. With suitable dimensioning, they also ensure that resonances which the capacitors form with the rest of the system and among one another are reduced to an acceptable degree. Furthermore, they convert some of the high-frequency interference signals that are to be filtered out by the RF filter device into heat, as a result of which the energy radiated in the RF range by the integrated circuit or the system containing the integrated circuit can be reduced. If these points are taken into account in the configuration of the RF filter device F1, F2, . . . Fn, then the latter proves to be particularly effective.

The above-described construction shown in the figure affords optimal protection against the propagation of high-frequency interference signals via lines carrying DC voltages or low-frequency voltages from and to the integrated circuit (the individual modules thereof) and other components of the system containing the integrated circuit. A protective effect that, although not quite so outstanding, is nonetheless still good is produced if the second capacitor, i.e. the capacitor C2, C4 or C6, is omitted in individual or all of the RF filter devices F1, F2, . . . Fn, that is to say the RF filter devices contain only the first capacitor and the resistor, or if the first capacitor, i.e. the capacitor C1, C3, or C5, is omitted in individual or all the RF filter devices, in other words the RF filter devices only contain the second capacitor and the resistor, or if the second capacitor and, in addition, also the resistor are omitted in individual or all of the filter devices, in other words the RF filter devices F1, F2, . . . Fn only contains the first capacitor.

It should be apparent that the integrated circuit described can be modified in diverse ways.

In particular, there is no restriction to the effect that the RF filter devices prevent or restrict the propagation of high-frequency interference signals via the supply lines used for power supply purposes. The RF filter devices of the type described above can also prevent or restrict the propagation of high-frequency interference signals via arbitrary other lines carrying DC voltages or low-frequency voltages.

Furthermore, there is no restriction to the effect that exactly one RF filter device is provided per module. In principle, as many RF filter devices as desired may be provided for the individual modules, independently of one another.

Moreover, there is no restriction with regard to the number and content of the modules of the integrated circuit. As many modules as desired may be provided and, independently of one another, they may be of any desired size and contain any desired constituent parts of the integrated circuit.

Finally, there is also no restriction to the effect that the integrated circuit has a plurality of modules. The RF filter devices of the type described can also advantageously be used in integrated circuits constructed in any other way.

The integration of the RF filter device in the integrated circuit is, independently of the details of the practical realization of the integrated circuit and of the RF filter device, a very simple yet very effective possibility for preventing interference with the operation of the integrated circuit by high-frequency interference signals and/or interference with other integrated circuits or other system components by high-frequency interference signals generated by the integrated circuit.

We claim:

1. An integrated circuit, comprising:
lines, including a first line and a second line, for carrying one of DC voltages and low-frequency voltages; and
a radio-frequency (RF) filter device connected to said lines and preventing and restricting a propagation of high-frequency interference signals through said lines.

2. The integrated circuit according to claim 1, including component parts connected to said RF filter device, said RF filter device is disposed, constructed and dimensioned such that said component parts are protected against the high-frequency interference signals transmitted through said lines and fed to said component parts.

3. The integrated circuit according to claim 2, wherein said component parts generate and output further high-frequency interference signals carried by said lines, and said RF filter device is disposed, constructed and dimensioned such that said RF filter device filters out the further high-frequency interference signals generated and output by said component parts and carried on said lines.

4. The integrated circuit according to claim 1, including component parts connected to said lines and generating and outputting further high-frequency interference signals carried by said lines, said RF filter device is disposed, constructed and dimensioned such that said component parts are protected against the high-frequency interference signals and also protected against the further high-frequency interference signals generated within the integrated circuit.

5. The integrated circuit according to claim 1, including component parts to be protected against the high-frequency interference signals, said RF filter device is disposed in direct proximity and connected to said component parts for suppressing the high-frequency interference signals, and said component parts generating further high-frequency interference signals also being suppressed by said RF filter device to prevent interferences in others of said component parts and to parts external to the integrated circuit.

6. The integrated circuit according to claim 1, including component parts connected to said RF filter device, said RF filter device is disposed, constructed and dimensioned such that said RF filter device filters out the high-frequency interference signals transmitted through said lines supplying energy required for operation, said component parts generating further high-frequency interference signals and said RF filter device suppressing the further high-frequency interference signals to prevent interference in others of said component parts and to parts external to the integrated circuit.

7. The integrated circuit according to claim 1, wherein said RF filter device has a capacitor, through which said first line from which said RF filter device is intended to remove the high-frequency interference signals is connected to a reference-ground potential.

8. The integrated circuit according to claim 7, wherein said RF filter device has a resistor inserted into said first line from which said RF filter device is intended to remove the high-frequency interference signals.

9. The integrated circuit according to claim 8, wherein said RF filter device has a further second capacitor, through which said first line from which said RF filter device is intended to remove the high-frequency interference signals is connected to the reference-ground potential.

10. The integrated circuit according to claim 8, including component parts generating further high-frequency interference signals and connected to said lines, said resistor and said capacitor form a low-pass filter at least partially preventing the high-frequency interference signals from reaching said component parts which are to be protected against the high-frequency interference signals, and said RF filter device suppressing the further high-frequency interference signals from each of said component parts from reaching other ones of said component parts and from reaching outside of the integrated circuit.

11. The integrated circuit according to claim 9, including component parts each generating further high-frequency interference signals and connected to said lines, said resistor and said further capacitor form a low-pass filter at least partially preventing the high-frequency interference signals from reaching said component parts which are to be protected against the high-frequency interference signals by said RF filter device, and said RF filter device suppressing the further high-frequency interference signals from each of said component parts from reaching other ones of said component parts and from reaching outside of the integrated circuit.

12. The integrated circuit according to claim 8, wherein said capacitor is dimensioned such that energy fed through said lines, connected to said RF filter device, can be drawn completely from said capacitor given one of regular and continuous recharging of said capacitor; and including component parts each generating further high-frequency interference signals and connected to said lines, said RF filter device protecting said component parts against the high-frequency interference signals, and said RF filter device suppressing the further high-frequency interference signals of each of said component parts from reaching other ones of said component parts and from reaching outside of the integrated circuit.

13. The integrated circuit according to claim 12, wherein said resistor is dimensioned such that a current flowing through said resistor during operation suffices to keep said capacitor continually charged to such an extent that the energy fed through said lines provided with said RF filter device to said component parts can be drawn completely from said capacitor.

14. The integrated circuit according to claim 10, wherein said resistor is dimensioned such that said low-pass filter prevents a flowing of the high-frequency interference signals.

15. The integrated circuit according to claim 9, wherein said resistor is dimensioned such that resonances which said capacitor and said further capacitor form with a rest of a system and among one another are reduced to a degree which does not interfere with an operation of the integrated circuit.

16. The integrated circuit according to claim 8, wherein said resistor is dimensioned such that said resistor converts the high-frequency interference signals filtered out by said RF filter device at least partially into heat.

17. The integrated circuit according to claim 1, including a plurality of component parts, and said RF filter device is one of a plurality of RF filter devices each connected to different ones of said component parts.
